(19) United States
(12) Patent Application Publication
(10) Pub. No.: US 2008/0150548 A1
(43) Pub. Date: Jun. 26, 2008

(54) TEST CARTRIDGE WITH INTERNAL GENERATION OF THE TEST SIGNALS

(75) Inventor: Daniela Brazzeli, Busto Arsizio (VA) (IT)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.R.L., Agrate Brianza (IT)

(21) Appl. No.: 11/961,266

(22) Filed: Dec. 20, 2007

(30) Foreign Application Priority Data
Dec. 22, 2006 (IT) MI2006A002497

(51) Int. Cl. G01R 1/04

(52) U.S. Cl. 324/555

(57) ABSTRACT

A test cartridge for testing an electronic device is provided. The test cartridge includes a housing for housing the electronic device, a contact for electrically contacting the electronic device and a coupling device for keeping the electronic device coupled with the contact. The test cartridge further includes test circuitry for generating test signals adapted to carry out a test of the electronic device; the test circuitry being electrically connected with the contact for providing the test signals to the electronic device.

### BACKGROUND OF THE INVENTION

1. Field of the Invention

The present invention relates to the electronic field. More particularly, the present invention relates to testing of electronic devices.

2. Discussion of the Related Art

Electronic devices, and in particular Integrated Circuits (ICs), need to undergo test operations. The purpose of each test operation is to verify that each electronic device operates in a correct way according to the desired specifications. In this way it is possible to guarantee the full functionality of the electronic devices and to improve the yield of the production processes that have been used. Indeed, each electronic device that has been produced may be affected by a plurality of imperfections or defects due to unavoidable production drawbacks caused by the tolerances of the processes that have been used.

The modern apparatuses that are typically used for testing the ICs (herein referred to as “probers”) carry out the test operations directly at wafer-level: the ICs included in the wafer undergo a parallel test prior to being separated from the wafer itself. In particular, in order to be capable of executing the test operations in parallel on a plurality of ICs, the probers typically include a complex apparatus (“probe card”) that allow contacting each pad of each IC of the wafer to a corresponding probe. During the test operations, such probes provide electrical signals that stimulate the IC's functioning. Based on the received stimulus, the ICs that undergo the test generate response signals, which are received and sensed by further probes of the probe card for the purpose of evaluating their correct functioning.

The prober mainly consists of two parts, which can be considered to be distinct from each other: a first part, essentially a mechanical one, has the purpose of aligning the probe card to the wafer to be tested; a second part, essentially an electrical/electronic one, has instead the purpose of generating the signals for stimulating the circuits integrated in the wafer and receiving and interpreting the signals generated by said circuits in response to the stimulations. During the electronic phases of the test, the mechanical part of the prober does not execute any particular operation, since it only keeps the position of the probe card with respect to the wafer and the contact between the probes and the pads fixed. As a consequence, during the electronic phases (which typically have long durations), the mechanical part of the prober remains (inefficiently) idle. Said drawback is particularly felt in modern integrated circuits, since, because of the ever increasing integration density, the test operations have a long duration; this has a significant impact on the total production costs.

In order to prevent this drawback, a known solution provides for decoupling the mechanical phase from the electronic phases.

For example, international patent application WO 01/04641 discloses a system for testing integrated circuits at the wafer level that makes use of dedicated test cartridges for executing tests in a “burn-in” mode, i.e., at high temperatures. Particularly, each wafer to be tested is inserted into a corresponding test cartridge that includes a dedicated probe card. By adopting said system, the prober only includes the mechanical part that has the purpose of inserting the wafer into the cartridge and aligning it to the corresponding probe card. Once the alignment has been accomplished, the test cartridge is sealed, and the alignment is maintained by locking structures that are inside the test cartridge itself. The prober carries out said alignment operations in succession on a plurality of cartridges, which are then connected to a common test machine; said test machine comprises an electric/electronic structure that provides for the generation of the stimulus signals required for testing the operation of the integrated circuits arranged in the test cartridges and for guaranteeing its power supply, as well as for receiving and interpreting the corresponding response signals. In this way, the prober may be exploited in a more efficient way, thereby reducing the whole test times.

However, in the abovementioned solution, the test machine has a very large size, having to be capable of housing a high number of test cartridges. In any case, the test cartridges have to be kept connected to the test machine during the electronic phases. Therefore, the number of integrated circuits that can be tested simultaneously is limited by the sizes of the test machine.

### SUMMARY OF THE INVENTION

Substantially, the present invention is based on the idea of generating the signals that are required for executing the test directly within the cartridges.

Particularly, the present invention provides a solution as set forth in the independent claims.

Advantageous embodiments are described in the dependant claims.

Particularly, an aspect of the present invention provides a test cartridge for testing an electronic device. The test cartridge includes housing means for housing the electronic device, contacting means for electrically contacting the electronic device and coupling means for keeping the electronic device coupled with the contacting means. The test cartridge further includes testing means for generating test signals adapted to perform a test of the electronic device; the electronic means is electrically connected with the contacting means for providing the test signals to the electronic device.

In a specific implementation of the invention, the testing means is adapted to determine and store a result of the test.

According to an embodiment of the invention, the testing means includes a housing for an electric battery.

According to an embodiment of the invention, the testing means enables the generation of the test signals in response to the receipt of the electric supply and the coupling between the electronic device and the contacting means.

In an embodiment of the invention, the test signals include signals for stimulating the electronic device.

According to an embodiment of the invention, the testing means may be assembled in a detachable way.

According to an embodiment of the invention, means for sensing an alignment between the electronic device and the contacting means is provided.

A further aspect of the invention provides a corresponding method for testing an electronic device.

According to an embodiment of the invention, the test method provides for storing the test cartridge in a warehouse; the generation of the test signals is executed after the test cartridge has been stored.

Alternatively, the test method provides for transporting the test cartridge with a vehicle, and generating the test signals during the transport.

### BRIEF DESCRIPTION OF THE DRAWINGS

The invention itself, as well as further features and the advantages thereof, will be best understood with reference to the following detailed description, given purely by way of a non-restrictive indication, to be read in conjunction with the accompanying drawings. In this respect, it is expressly intended that the figures are not necessarily in scale and that, when otherwise indicated, they are to be simply intended to conceptually illustrate the structures and the procedures described. Particularly:

FIG. 1 schematically illustrates a test cartridge according to an embodiment of the invention; and

FIG. 2 is a schematic block diagram that illustrates a test procedure (which makes use of the test cartridge of FIG. 1) according to an embodiment of the invention.

### DETAILED DESCRIPTION

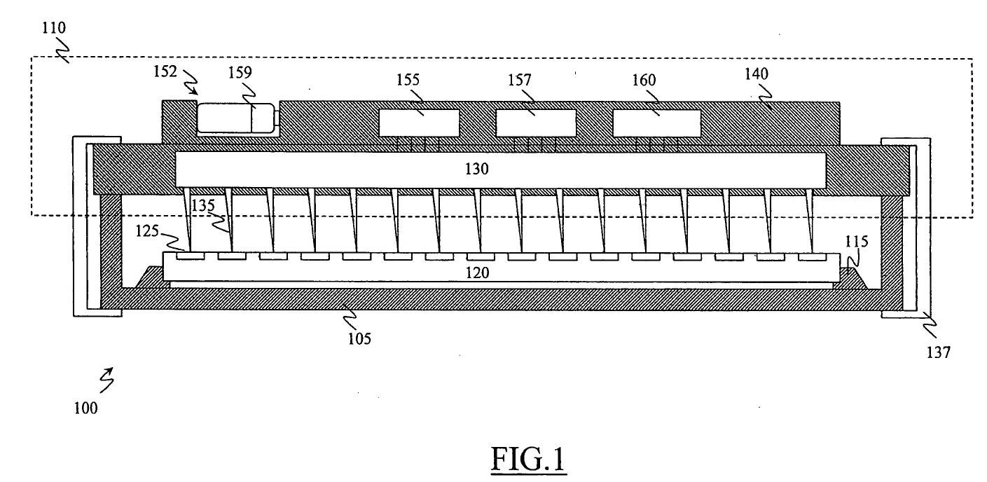

With reference to FIG. 1, a section of a test cartridge 100 is schematically illustrated. Particularly, the test cartridge 100 includes a base 105 and a lid 110.

The base 105 includes a housing 115 adapted to receive a wafer 120 of semiconductor material and to keep it locked to the base 105. The wafer 120 includes a plurality of electronic circuits to be tested (not shown in the figure) each one having a plurality of pads 125 for receiving and providing electric signals.

The lid 110 comprises an integrated probe card 130, having a plurality of probes 135; the probes 135 are used for establishing an electric contact with the pads 125 of the wafer 120 for the purpose of providing the stimulus and supply signals, and for receiving response signals generated by the circuits integrated in the wafer 120. The test cartridge 100 further includes one or more mechanical locks 137 (for example, jaws) for firmly locking the lid 110 to the base 105 of the test cartridge 100; in this way it is possible to keep the alignment between the wafer 120 and the probes 135 fixed.

In the solution according to an embodiment of the present invention (as it will be described in the following), the probe card 130 is further connected to a test device 140.

Particularly, the test device 140 includes a stimulus generator 155 for the generation of stimulus signals required to execute the test. The complexity of the stimulus generator 155 and the type of stimulus signals being generated depends both on the type of test that is desired to be performed, and on the type and complexity of the circuits integrated in the wafer 120. Naturally, the more complex the circuit to be tested, the longer and more complicated the test to be executed, and, consequently, the more complex the structure of the stimulus generator. In case the circuits integrated in the wafer 120 are of the BIST type (Built In Self Test, i.e., having at their interior all or almost all the circuit components capable of managing its test), the stimulus generator 155 would have on the contrary a very simple structure, since its only function would be the generation of an enabling signal for initiating the test, which is instead automatically managed by the circuits integrated in the wafer 120.

Summarizing, the various stimulus signals are directly generated by the stimulus generator 155, and are transmitted to the circuits integrated in the wafer 120 by the probe card 130 trough the probes 135. Consequently, the test cartridge 100 does not have to remain connected to any test machine. In this way it is possible to test whichever number of integrated circuits simultaneously; this allows saving a great amount of time, and thus scaling down the test costs.

In an embodiment of the present invention, the stimulus generator 155 and/or the probe card 130 are detachable from the test device 140, in such a way to be replaced by a different stimulus generator and a different probe card. In this way, it is possible to use the same cartridge for testing different integrated circuits, by simply changing the stimulus generator 155 and the probe card 130.

The test device 140 further includes an alignment sensor 157, adapted to verify if the wafer 120 and the probe card 130 are correctly aligned. In this way, it is the test cartridge 100 itself that signals when said alignment has occurred, and not a dedicated external machine.

The test device 140 further includes a housing 158 for a battery 159, which is required for supplying the test circuit 140. Thanks to the presence of such battery 159, the test cartridge 100 is capable of operating in an autonomous way, without having to be connected to further machines. Thanks to this property, the test cartridge may execute the test operations in any condition.

Finally, the test device 140 includes a memory 160 (preferably of the non-volatile type) for saving the response signals generated by the integrated circuits during the test. In this way, it is possible to control the result of the test at any time subsequent to the test completion.

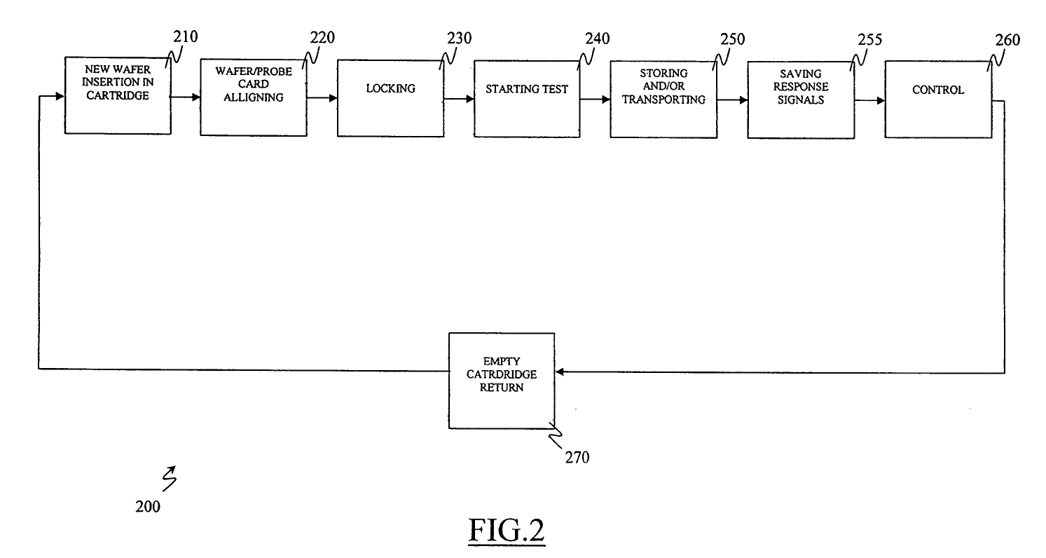

For the purpose of effectively describing the operation of the test cartridge 100 according to an embodiment of the present invention, reference will be made to the FIGS. 1 and 2. Particularly, FIG. 2 illustrates, by means of a block diagram 200, the main phases that form an exemplary test procedure that makes use of the test cartridge 100.

The first phase of the test procedure comprises inserting the wafer 120 to be tested within the test cartridge 100 (phase 210). More particularly, the wafer is inserted into the housing 115, in such a way to be kept locked to the base 105 of the cartridge 100 during the following phases of the test. The housing 115 is necessary for guaranteeing a mechanical resistance to the whole structure cartridge-wafer that is sufficient for maintaining the alignment of the probe card 130 to the wafer 130 (which is obtained in the following phases) in presence of shocks and vibrations.

After the wafer 120 has been locked to the base 105, the lid 110 of the test cartridge 100 is placed on the base 105 by a prober (not shown in the Figure). At this point, the prober starts executing the operations necessary for aligning the lid 110 (and, thus, the probe card 130) to the wafer (phase 220). Substantially, the lid 110 slides (along the directions of the plane including the lid 110 itself) on the base 105 until all the probes 135 of the probe card 130 are in correspondence with the respective pads 125 on the wafer 120, in such a way that the circuits integrated in the wafer 120 may receive/provide from/to the probe card 130 the requested electric signals. Because of the high integration scale with which present circuits are integrated, the sizes of the pad of each integrated circuit and the respective distances among the various pads are very small. Consequently, the alignment phase has to be executed with particular attention by a prober having a sufficient accuracy. For this purpose, the alignment procedure comprises two phases: a “raw” alignment phase followed by a “fine” alignment phase. The wafer 120 includes a number of easily accessible alignment pads (not shown in the Figure), which provide reference points to the prober for carrying out the “raw” alignment. Particularly, the lid 110 slides until the alignment pads are in correspondence with suitable probes 135 of the probe card 130. The prober is informed of the accomplished (raw) alignment by means of the alignment sensor 157, which is capable of sensing, through the transmission and the reception of electric signals, if the probes 135 have established or not an electric contact with the reference pads. For example, the reference pads may be connected to particular circuits integrated in the wafer that, if properly stimulated by the alignment sensor 157 through electric signals provided to the probes 135, respond by generating predetermined response signals that are interpretable by the alignment sensor 157 itself. Having received said response signals, and having interpreted them as correct, the alignment sensor 157 informs the prober that the raw alignment has been accomplished. At this point, the alignment is improved in the fine alignment phase with the aid of known optical sensing devices, for example, by means of lasers or infrared sensors, which allow establishing whether all the probes 135 have been correctly positioned or not with the sufficient precision.

The lid 110 is then locked to the base 105 by means of the mechanical locks 137 (phase 230) for maintaining the position wafer/probe obtained during the previous phase fixed. In this way, the prober does not need to execute further operations on the test cartridge 100, since the task of maintaining the alignment is entirely carried out by the mechanical locks 137.

At this point, the test cartridge 100 is capable of executing the real test phase in a completely autonomous way. Indeed, both the test circuit 140 and the wafer 120 are supplied by means of the battery 159 inserted in the housing 158 of the lid 110. Moreover, the stimulus signals that are necessary for executing the test are directly provided by the test cartridge 100, being generated by the stimulus generator 155.

Particularly, the test is triggered by the stimulus generator 155 (phase 240) as far as it is supplied by the battery 159 and the lid 110 is locked to the base 105. The test cartridge may be moved, and stored in a warehouse or transported to the place wherein the circuits integrated in the wafer 120 are separated from the wafer itself and then assembled (phase 250). By using the cartridge 100 it is possible to save significant amounts of time. Indeed, the test phase during which the stimulus signals are provided to the circuits integrated in the wafer 120, which can have long durations because of the complexity of the circuits and the desired type of test, may be carried out during the dead times that occur during the course of whichever modern technological industrial process. For example, the test may proceed during the storing of the test cartridges 100 in the warehouse, waiting to be sent elsewhere. In addition or alternatively, the test may be completed on vehicles (for example, trucks, trains or ships) that are used for the transport of the test cartridges to further plants.

For this purpose, the environment in the test cartridge 100 formed by the wafer 100, the probe card 130 and the stimulus generator 155 is kept insulated from external interferences, and is capable of acting in an autonomous way. Particularly, the housing 115 and the mechanical locks 137 generates a firm and robust coupling; this avoiding that too violent a hit or a vibration of proper frequency and intensity may cause the alignment of the probes 135 of the probe card 130 with the corresponding pads 125 to be lost, thereby interrupting the test operations or altering its results.

During execution of the test operations, the circuits integrated in the wafer 120 generate response signals corresponding to the stimulus signals, Said response signals are provided to the test circuit 140 through the probes 135, and they are saved into the memory 160 (phase 255). Preferably, said event is also signaled to the outside of the test cartridge 100 (for example, by means of a signaling device, e.g., an led).

At this point (for example, when the cartridges are taken from the warehouse or when they arrive at a destination) it is possible to analyze the pattern of the response signals for determining the test result (phase 260). For example, the test cartridge 100 may be connected to a machine that is capable of reading the content of the memory 160, in such a way to establish which circuits integrated in the wafer 120 are operative and which circuits are defective.

Subsequently, the circuits integrated in the wafer 120 are separated from the wafer. The integrated circuits whose test has given a positive outcome are assembled, while the ones that are defective are discarded or returned to the production plant.

The last phase of the test procedure comprises the return of the empty cartridge (phase 270), which can be reused for testing a further wafer 120.

Naturally, in order to satisfy local and specific requirements, a person skilled in the art may apply to the solution described above many modifications and alterations. More specifically, although the present invention has been described with a certain degree of particularity with reference to preferred embodiment(s) thereof, it should be understood that various omissions, substitutions and changes in the form and details as well as other embodiments are possible; moreover, it is expressly intended that specific elements and/or method steps described in connection with any disclosed embodiment of the invention may be incorporated in any other embodiment as a matter of general design choice.

For example, analog considerations can be applied if the test cartridge has a structure that is different from that described but with equivalent features; in particular, the housing for the wafer may be positioned on the base of the cartridge in positions that are different than the described one.

Moreover, even if in the description the mechanical locks are of the jaw type, equivalent locks could be used, such as, for example, expansion pins.

Also, one or more of the components of the test circuit (the stimulus generator, the battery housing, the alignment sensor and/or the memory) may be disposed in the base of the cartridge instead of in the lid (properly connected with the probe card integrated in the lid).

Although in the description reference has been explicitly made to test cartridges for testing circuits integrated in wafers of semiconductor material, nothing prevents using the test cartridges for testing electronic circuits that are already assembled in packages or on assembly boards.

In some cases, the memory may be omitted, for example if the circuits integrated in the wafer are of the BIST type, and include a dedicated memory for the test.

Without departing from the principles of the invention, the battery housing may be substituted (or added) by a connector for receiving an external supply; in this case, the cartridge has to be maintained connected to the external supply for the entire duration of the test (for example, said external supply may be provided by the AC mains when the cartridges are stored in the warehouse, or by a generating set when the cartridges are transported on vehicles).

Furthermore, the triggering of the test phase, i.e., the triggering of the generation of the stimulus signals, may occur both in an automatic way (as previously described) and in response to an external signal.

Although it has been explained that both the stimulus generator and the probe card are detachable, the cost of the single test cartridge may be significantly reduced if the cartridge and/or the probe card are fixed, and not detachable.

An alternative embodiment, although less effective, leaves the task of sensing the alignment of the wafer/probe card entirely to the prober, thereby simplifying the test cartridge's structure (the presence of the alignment sensor no longer needed).

Similar considerations apply if the test method provides for the execution of an equivalent procedure, by using similar steps, removing some non-essential steps, or adding further optional steps (for example, performing all or some of the steps needed for carrying out burn-in tests, wherein the cartridge is brought to high temperatures).

Alternatively, the generation of the stimulus signals may be enabled only when the test cartridges are stored in the warehouse (or in another equivalent environment).

Furthermore, nothing prevents executing the test procedure during the transportation on any other vehicle (for example, planes).

Although in the description reference has been made to a test cartridge capable of carrying out the test operations simultaneously on all the electronic circuits of the wafer, said test operations may be carried out in a serial way on a reduced number of electronic circuits at the time (said solution may be preferably used when the battery of the test cartridge is not capable of managing the generation of a high number of simultaneous stimulus signals).

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A test cartridge for testing an electronic device, the test cartridge including:
housing means for housing the electronic device;
contacting means for electrically contacting the electronic device; and
coupling means for keeping the electronic device coupled with the contacting means, and
test means for generating test signals adapted to carry out a test of the electronic device, the test means being electrically connected with the contacting means for providing the test signals to the electronic device.

2. The test cartridge of claim 1, wherein the test means includes:
means for receiving a response to the test signals from the electronic device through the contacting means;
means for determining an outcome of the test based on the response; and
means for storing the outcome of the test.

3. The test cartridge of claim 1, wherein the test means includes a housing for an electric battery adapted to provide an electric supply to the test means.

4. The test cartridge of claim 1, wherein the test means comprises means for enabling generation of the test signals in response to reception of an electric supply and to coupling between the electronic device and the contacting means.

5. The test cartridge of claim 1, wherein the test signals include stimulus signals for stimulating the electronic device during the test.

6. The test cartridge of claim 1, further comprising means for mounting the test means in a detachable way.

7. The test cartridge of claim 1, further comprising means for sensing an alignment between the electronic device and the contacting means.

8. A method for testing an electronic device comprising:
inserting the electronic device into a housing of a test cartridge;
electrically contacting the electronic device through contacting means;
keeping the electronic device coupled with the contacting means,
generating, through test means included in the test cartridge, test signals for executing a test of the electronic device; and
providing the test signals to the electronic device through contacting means.

9. The method of claim 8, further comprising:
receiving a response to the test signals from the electronic device through the contacting means;
determining an outcome of the test based on the response; and
storing the outcome of the test in the test cartridge.

10. The method of claim 8, further comprising housing an electric battery adapted to provide an electric supply to the test means in the test cartridge.

11. The method of claim 8, further comprising enabling the generation of test signals in response to reception of an electric supply and the coupling between the electronic device and the contacting means.

12. The method of claim 8, wherein providing the test signals includes providing stimulus signals for stimulating the electronic device.

13. The method of claim 8, further comprising sensing an alignment between the electronic device and the contacting means within the test cartridge.

14. The method of claim 8, further comprising mounting the test means in the test cartridge in a detachable way.

15. The method of claim 8, further comprising storing the test cartridge in a warehouse, generating the test signals and providing the test signals to the electronic device being carried out when the test cartridge is stored in the warehouse.

16. The method of claim 8, further comprising transporting the test cartridge on a vehicle, generating the test signals and providing the test signals to the electronic device being carried out during the transport.
